(19) United States
(12) Patent Application Publication
(10) Pub. No.: US 2021/0059075 A1
(43) Pub. Date: Feb. 25, 2021

(54) HEAT RADIATION COMPONENT AND MOUNTING SUBSTRATE

(71) Applicant: NEC Corporation, Tokyo (JP)

(72) Inventor: Tomoyuki MITSUI, Tokyo (JP)

(73) Assignee: NEC Corporation, Tokyo (JP)

(21) Appl. No.: 16/927,391

(22) Filed: Jul. 13, 2020

(30) Foreign Application Priority Data
Aug. 21, 2019 (JP) 2019-150823

(51) Int. Cl. H05K 7/20; G06F 1/20

(52) U.S. Cl. CPC H05K 7/20418; H05K 7/20163; H05K 7/20145; G06F 1/20

(57) ABSTRACT

In order to more satisfactorily cool a heat generation component without enhancing a blowing capacity of a fan, a heat radiation component is assumed to be covered by a wiring substrate and a cover portion that includes a first opening and a second opening, the heat radiation component including: a heat reception portion contacting with a heat generation component installed on the wiring substrate; and a plurality of heat radiation plates thermally connected to the heat reception portion, wherein a first part as a part included in the heat radiation plate and between the heat generation component and the first opening includes an end portion that is on a side more separated from the wiring substrate and whose distance from the wiring substrate decreases as being closer to the first opening.

This application is based upon and claims the benefit of priority from Japanese Patent Application No. 2019-150823, filed on Aug. 21, 2019, the disclosure of which is incorporated herein in its entirety by reference.

### TECHNICAL FIELD

The present invention relates to a structure for cooling a heat generation component.

### BACKGROUND ART

In recent years, an artificial intelligence technique and a big data analysis technique have been rapidly spreading. Accompanying this, a demand for higher-speed execution of arithmetic processing in a central processing unit (CPU) of a computer has been increasing. When performing arithmetic processing at a higher speed, the CPU generates an increased quantity of heat. For this reason, in order for the CPU to perform arithmetic processing at a higher speed, it is necessary to enhance performance of a heat radiation component that radiates, to an outside, heat generated by the CPU.

FIGS. 1 to 3 are concept diagrams illustrating a configuration of a mounting substrate 100 as an example of a general mounting substrate in which a heat radiation component for cooling a CPU is installed. FIG. 1 is a perspective view of the mounting substrate 100. FIG. 2 is a front view of the mounting substrate 100 viewed in a direction of an arrow 991a illustrated in FIG. 1. FIG. 3 is a side view of the mounting substrate 100 viewed in a direction of an arrow 991b illustrated in FIG. 1.

As illustrated in FIG. 2, the mounting substrate 100 includes a wiring substrate 104, a CPU 105, a heat radiation component 108, and a cover portion 102.

In the wiring substrate 104, unillustrated wirings are formed. To these wirings, unillustrated electric components other than the CPU 105 are connected.

The CPU 105 is fixed to the wiring substrate 104, and is connected to a part of the wirings. The CPU 105 is a heat generation component.

The cover portion 102 is installed on the wiring substrate 104 in such a way as to cover the heat radiation component 108. Around the heat radiation component 108 covered by the cover portion 102, a cooling flow flows in the direction of the arrow 991a by an unillustrated fan or the like. The cover portion 102 covers the heat radiation component 108, thereby causing the cooling flow from a first opening 941 to a second opening 942 to flow in the vicinity of the heat radiation component. The cover portion 102 is formed of resin, for example.

As illustrated in FIG. 2, the heat radiation component 108 includes a heat reception portion 107, a heat conduction plate 101, and a heat radiation plate group 103. The heat reception portion 107 closely contacts with an upper surface of the CPU 105, and transfers heat generated by the CPU 105 to the heat conduction plate 101. The heat reception portion 107 is a copper plate, for example.

The heat conduction plate 101 is a metal plate, and transfers heat received from the heat reception portion 107 to the heat radiation plate group 103. The heat conduction plate 101 is a copper plate, for example.

The heat radiation plate group 103 is constituted of a plurality of heat radiation plates 103a as illustrated in FIG. 2. The heat radiation plate 103a is a metal plate. Each of the heat radiation plates 103a is connected to the heat conduction plate 101. The heat radiation plate 103a includes a rectangular surface as illustrated in FIG. 3. The longitudinal direction of the heat radiation plate 103a is parallel to the arrow 991a. Each of the heat radiation plates 103a radiates heat received from the heat conduction plate 101 to a cooling flow that passes in the vicinity of the surfaces of the heat radiation plate 103a.

Thereby, in the mounting substrate 100, heat generated by the CPU 105 is radiated to an outside.

PTL 1 discloses a heat radiation component that includes a base including an attachment surface and a heat radiation surface with at least one heat generation body being attached to the attachment surface, and a heat radiation portion including a plurality of heat radiation plates standing on the heat radiation surface of the base.

PTL 2 discloses a heat radiation component that includes a base body, a heat reception area being formed on one surface of the base body and receiving a quantity of heat whose heat source is a heat generation element, and a plurality of heat radiation plates being formed on another surface of the base body and radiating the quantity of heat to refrigerant fluid.

PTL 3 discloses a heat radiation component including heat radiation plates whose leading end positions in a cooling flow passage direction are set in such a way that the leading end positions of the heat radiation plates in an area excluding the vicinity of a cooling fan are downstream of the leading end positions of the heat radiation plates in the vicinity of the cooling fan.

[PTL 1] International Publication WO 2010/109799

[PTL 2] Japanese Unexamined Patent Application Publication No. 2016-086018

[PTL 3] Japanese Unexamined Patent Application Publication No. 2008-140802

However, in the mounting substrate 100 illustrated in FIGS. 1 to 3, there is a problem that a cooling flow in the direction of the arrow 991a does not easily pass through the heat radiation plate group 103. This is because vortex flows are generated on the right side and the left side of the heat radiation plate group 103 illustrated in FIG. 3. The vortex flow includes a component in a direction opposite to the arrow 991a. Thus, when the vortex flows are generated, the cooling flow does not easily flow in the direction of the arrow 991a. As a result, a flow quantity of the cooling flow is reduced, and the heat radiation component is not easily cooled. In order to restore the flow quantity, a flow pressure of the cooling flow sent out in the direction of the arrow 991a by the fan may be increased. However, for this purpose, the fan capable of generating a larger flow pressure needs to be used. Such a fan is expensive, and causes noise and an increase in drive electric power.

### SUMMARY

An object of the present invention is to provide a heat radiation component and the like capable of more satisfactorily cooling a heat generation component without increasing a flow pressure of a cooling flow.

A heat radiation component according to the present invention is assumed to be surrounded by a wiring substrate and a cover portion that includes a first opening and a second opening, the heat radiation component including: a heat reception portion contacting with a heat generation component installed on the wiring substrate; and a plurality of heat radiation plates thermally connected to the heat reception portion, wherein a first part as a part included in the heat radiation plate and between the heat generation component and the first opening includes an end portion that is on a side more separated from the wiring substrate and whose distance from the wiring substrate decreases as being closer to the first opening.

The heat radiation component according to the present invention can more satisfactorily cool a heat generation component without increasing a flow pressure of a cooling flow.

### BRIEF DESCRIPTION OF THE DRAWINGS

Exemplary features and advantages of the present invention will become apparent from the following detailed description when taken with the accompanying drawings in which:

FIG. 1 is a concept diagram (part 1) illustrating a configuration example of a general mounting substrate in which a heat radiation component is installed;

FIG. 2 is a concept diagram (part 2) illustrating the configuration example of the general mounting substrate in which the heat radiation component is installed;

FIG. 3 is a concept diagram (part 3) illustrating the configuration example of the general mounting substrate in which the heat radiation component is installed;

FIG. 4 is a concept diagram (part 1) illustrating a configuration example of a mounting substrate according to the present example embodiment in which a heat radiation component is installed;

FIG. 5 is a concept diagram (part 2) illustrating the configuration example of the mounting substrate according to the present example embodiment in which the heat radiation component is installed;

FIG. 6 is a concept diagram (part 3) illustrating the configuration example of the mounting substrate according to the present example embodiment in which the heat radiation component is installed;

FIG. 7 is a diagram illustrating a result example of a thermal fluid simulation on distribution of heat flux in a section of a heat radiation plate in the general mounting substrate;

FIG. 8 is a concept diagram (part 1) illustrating a first configuration example of the mounting substrate capable of supplying a larger quantity of a cooling flow before being heated to a spot included in a heat radiation plate and close to a heat reception portion;

FIG. 9 is a concept diagram (part 2) illustrating the first configuration example of the mounting substrate capable of supplying a larger quantity of a cooling flow before being heated to the spot included in the heat radiation plate and close to the heat reception portion;

FIG. 10 is a concept diagram illustrating a function of a flow direction adjustment portion;

FIG. 11 is a concept diagram illustrating a second configuration example of the mounting substrate capable of supplying a larger quantity of a cooling flow before being heated to a spot included in a heat radiation plate and close to the heat reception portion; and

FIG. 12 is a concept diagram illustrating a minimum configuration of a heat radiation component according to an example embodiment.

### EXAMPLE EMBODIMENT

Next, a detailed explanation will be given for a first example embodiment with reference to the drawings.

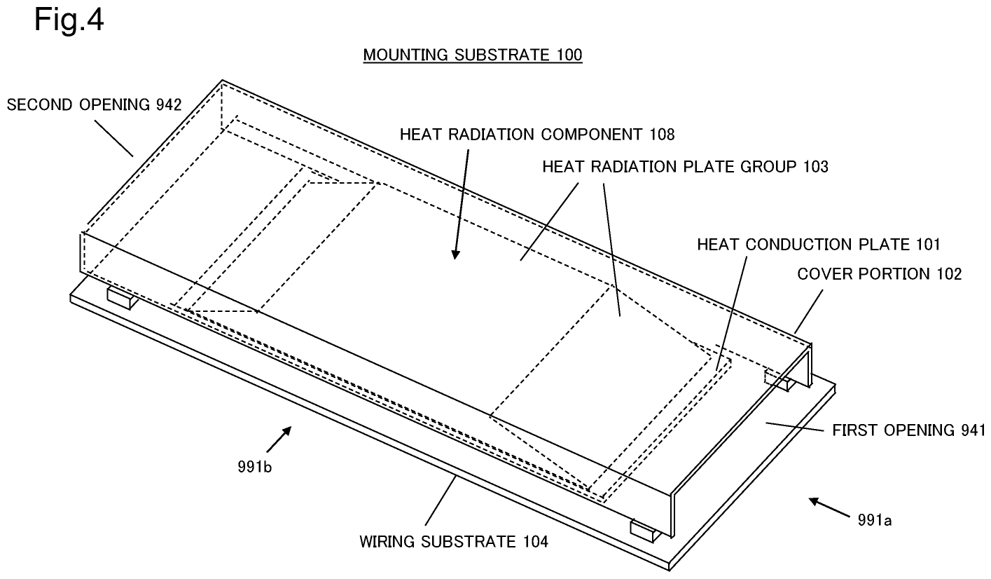

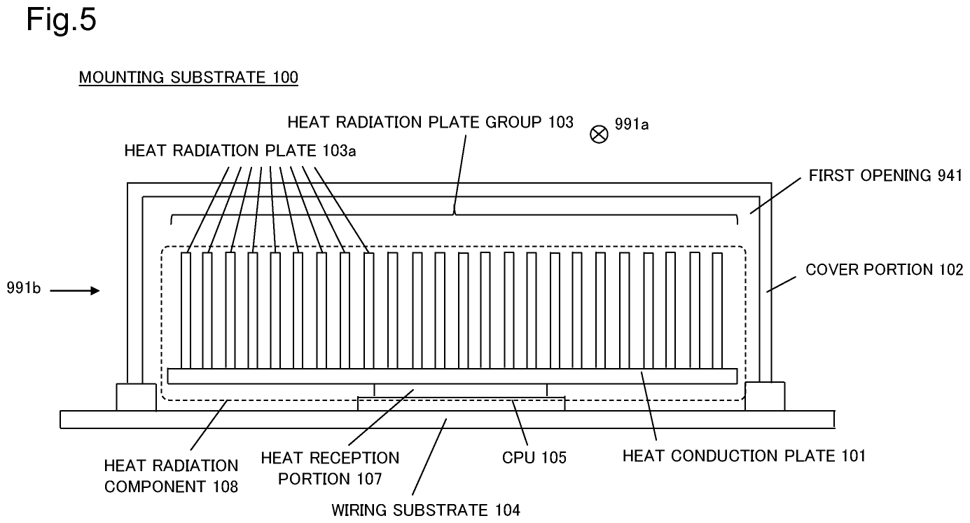

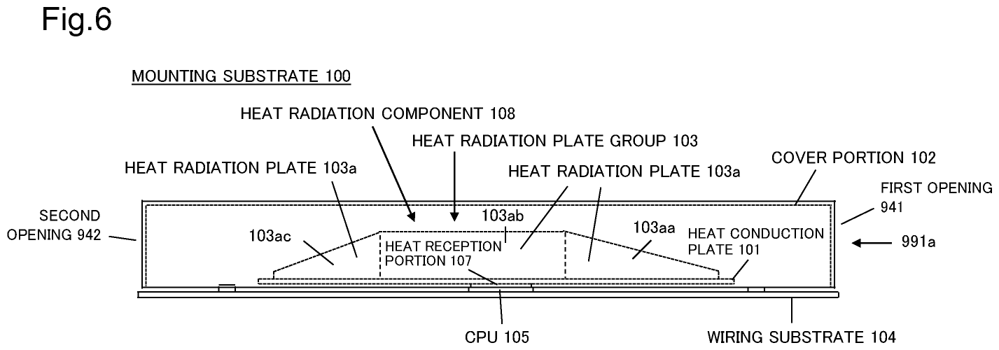

FIGS. 4 to 6 are concept diagrams illustrating a configuration of a mounting substrate 100 as an example of a mounting substrate according to the present example embodiment. FIG. 4 is a perspective view of the mounting substrate 100. FIG. 5 is a front view of the mounting substrate 100 viewed in the direction of an arrow 991a illustrated in FIG. 4. FIG. 6 is a side view of the mounting substrate 100 viewed in the direction of an arrow 991b illustrated in FIG. 4.

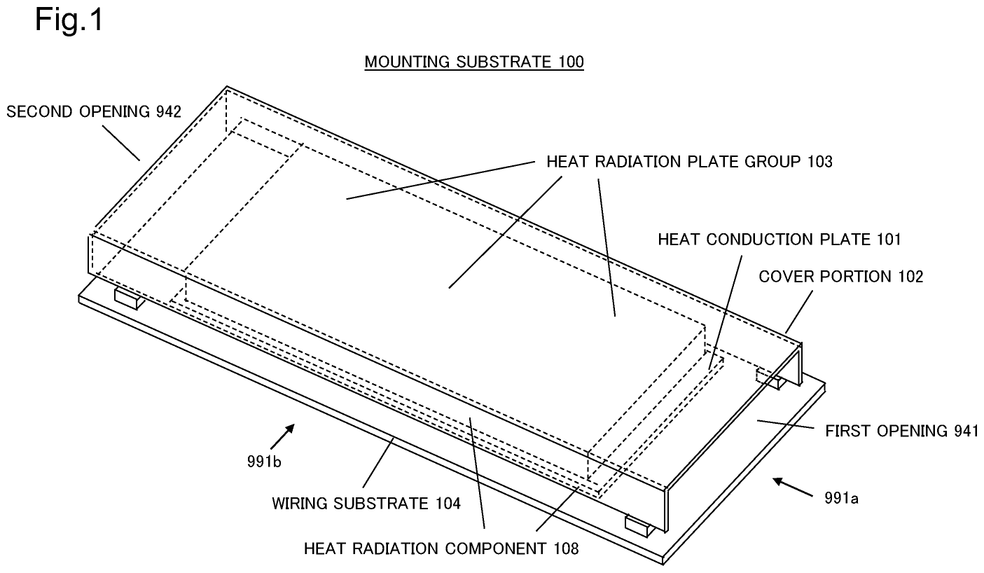

The mounting substrate 100 illustrated in FIGS. 4 to 6 differs from the mounting substrate 100 illustrated in FIGS. 1 to 3 in a shape of a heat radiation plate 103a (FIG. 5) constituting a heat radiation plate group 103.

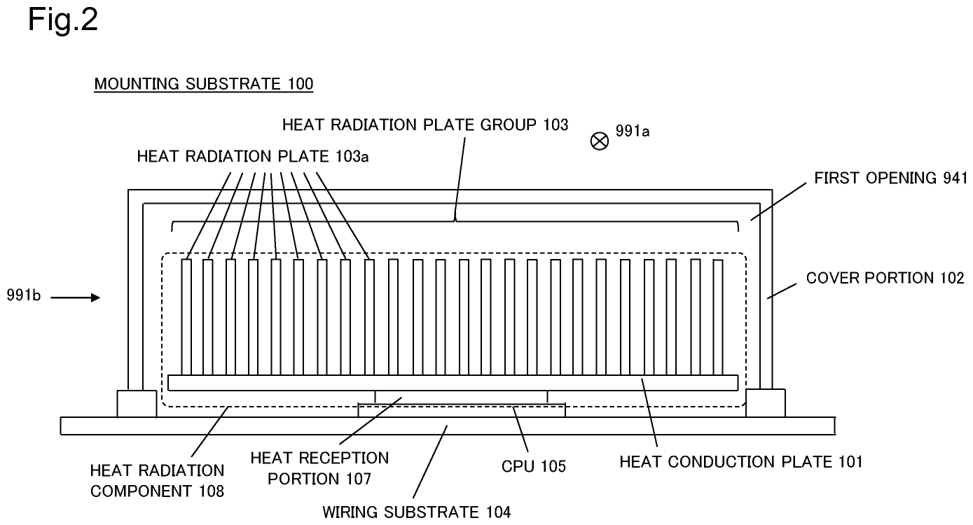

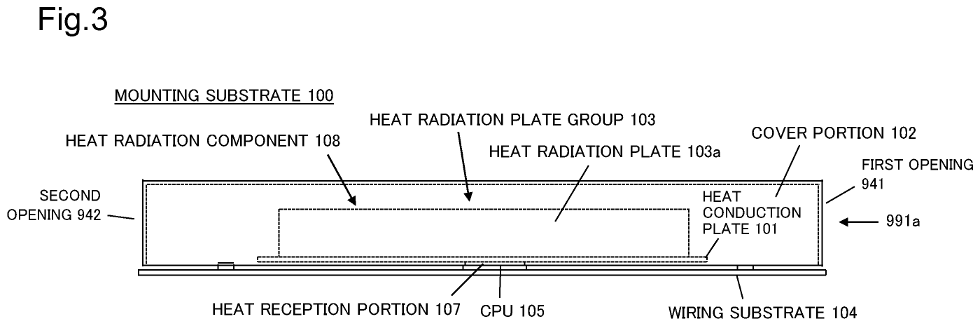

A front shape of the heat radiation plate 103a illustrated in FIG. 5 is the same as that illustrated in FIG. 2. However, a side surface shape of the heat radiation plate 103a illustrated in FIG. 6 differs from that illustrated in FIG. 3. In other words, while the heat radiation plate 103a illustrated in FIG. 3 has the rectangular shape, the heat radiation plate 103a illustrated in FIG. 6 includes a right portion 103aa, a center portion 103ab, and a left portion 103ac. In this regard, the right portion 103aa, the center portion 103ab, and the left portion 103ac constitute an integrated metal plate. A height of an upper end of the right portion 103aa from a wiring substrate 104 linearly decreases as a position is shifted to the right side. A height of an upper end of the left portion 103ac from the wiring substrate 104 linearly decreases as a position is shifted to the left side.

Thereby, when a cooling flow is supplied in the direction of the arrow 991a, vortex flows generated on the right side and the left side of the heat radiation plate group 103 in FIG. 6 become smaller than those in the mounting substrate 100 illustrated in FIGS. 1 to 3. As a result, in the mounting substrate 100 illustrated in FIGS. 4 to 6, a larger quantity of a cooling flow passes in the vicinity of the heat radiation plates 103a of the heat radiation plate group 103. Thus, in the mounting substrate 100 illustrated in FIGS. 4 to 6, the heat radiation plate group 103 can be cooled more satisfactorily. Heat of the heat radiation plate group 103 is supplied from a CPU 105 via a heat conduction plate 101 and a heat reception portion 107. Accordingly, in the mounting substrate 100 illustrated in FIGS. 4 to 6, the CPU 105 can be cooled more satisfactorily.

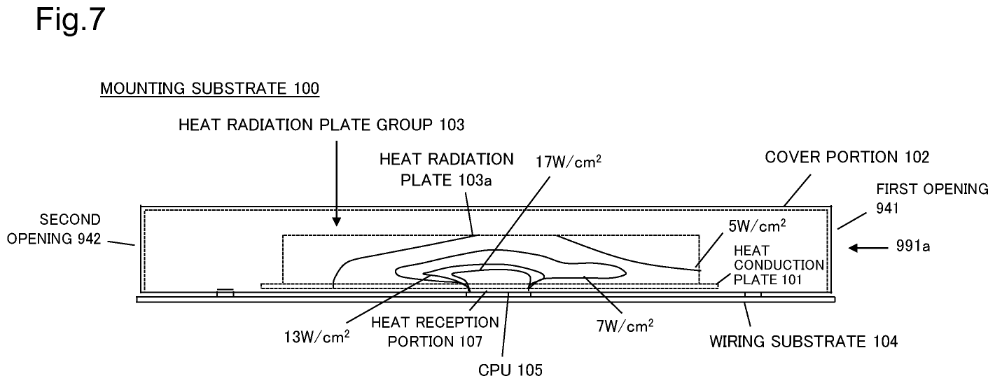

FIG. 7 is a diagram illustrating a result example of a thermal fluid simulation on distribution of heat flux in a section of the heat radiation plate 103a in the general mounting substrate 100 illustrated in FIGS. 1 to 3. Numbers given to W/cm² assigned to curves illustrated in FIG. 7 indicate heat flux (W/cm²) at positions along the curves in the section of the heat radiation plate 103a. A value of the heat flux tends to increase as a position approaches the heat reception portion 107.

Accordingly, it is considered that when a larger quantity of a low-temperature cooling flow before being heated can be supplied to a spot included in the heat radiation plate 103a and closer to the heat reception portion having a large heat flux value, the heat radiation plate is cooled more effectively.

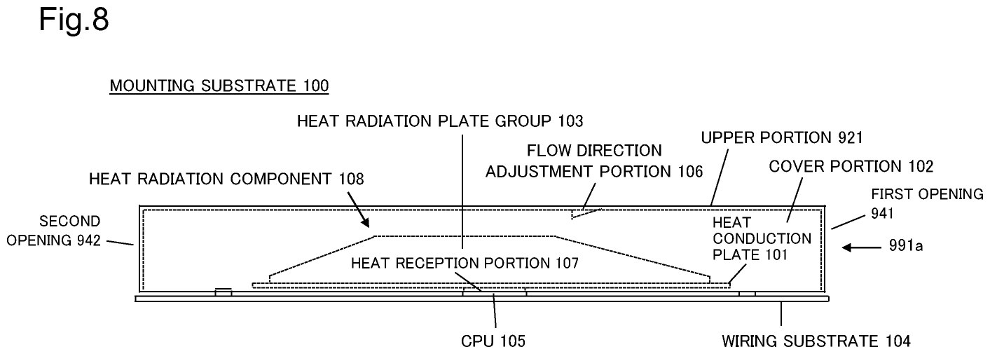

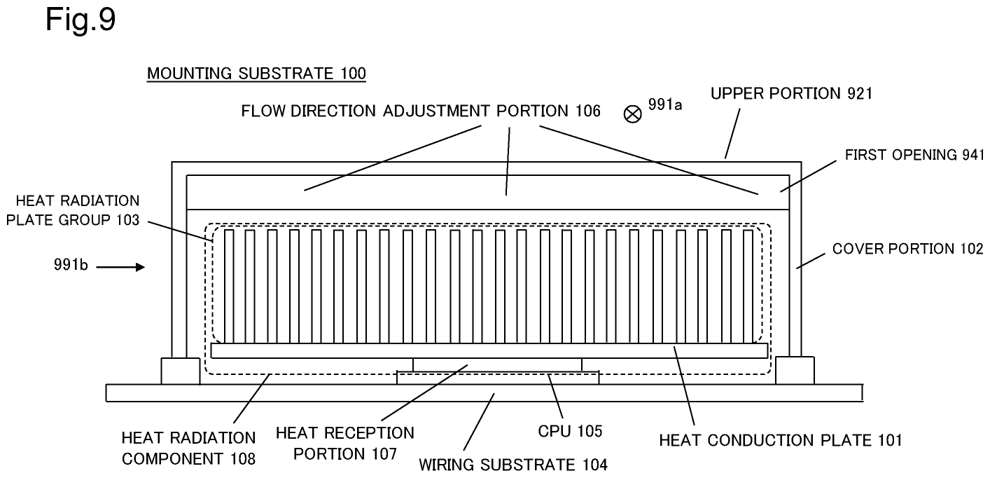

FIGS. 8 and 9 are concept diagrams illustrating a first configuration example of the mounting substrate 100 capable of supplying a larger quantity of a cooling flow before being heated to a spot included in the heat radiation plate 103a and close to the heat reception portion 107. FIG. 8 is a side view of the mounting substrate 100. FIG. 9 is a front view of the mounting substrate 100 viewed in the direction of an arrow 991a illustrated in FIG. 8.

The mounting substrate 100 illustrated in FIGS. 8 and 9 includes a flow direction adjustment portion 106 on a lower surface of an upper portion 921 of the cover portion 102. In the flow direction adjustment portion 106, a left surface illustrated in FIG. 8 is set facing a side on which the heat reception portion 107 exists.

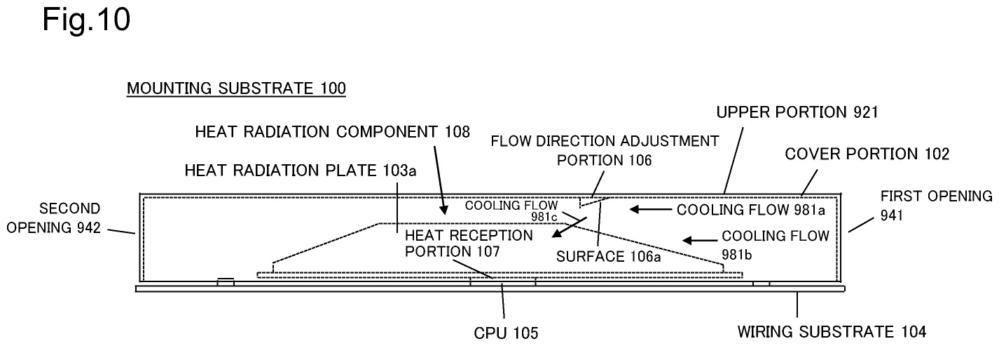

FIG. 10 is a concept diagram illustrating a function of the flow direction adjustment portion 106. A cooling flow 981a as an upper part of a cooling flow that has entered a part covered by the cover portion 102 collides with a surface 106a of the flow direction adjustment portion 106, and becomes a cooling flow 981c. The cooling flow 981c merges with a cooling flow 981b as a lower part of the cooling flow, and flows toward a part included in the heat radiation plate 103a and in the vicinity of the heat reception portion 107. Thereby, before heated by the heat radiation plate 103a, a larger part of the cooling flow reaches the part included in the heat radiation plate 103a and in the vicinity of the heat reception portion 107 having large heat flux. Then, a larger part of the cooling flow receives a large quantity of heat from the part included in the heat radiation plate 103a and in the vicinity of the heat reception portion 107, and flows in the left direction in FIG. 10. Thus, the flow direction adjustment portion 106 enables more effective cooling of the heat reception portion 107.

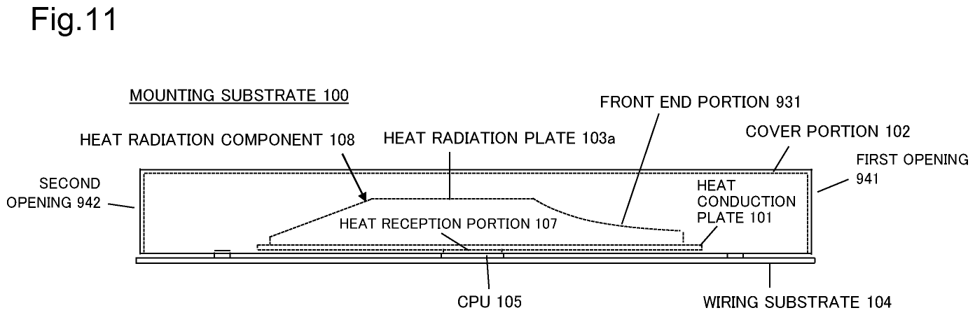

FIG. 11 is a concept diagram illustrating a second configuration example of the mounting substrate 100 capable of supplying a larger quantity of a cooling flow before being heated to a spot included in the heat radiation plate 103a and close to the heat reception portion 107. FIG. 11 is a side view of the mounting substrate 100.

In the mounting substrate 100 illustrated in FIG. 11, a front end portion 931 of the heat radiation plate 103a has a shape of a non-straight and curved line that is convex downward and that has a height becoming higher on a more left side. In other words, a distance between the front end portion 931 and the wiring substrate 104 decreases as a position approaches a first opening 941, and a degree of the decrease becomes smaller as a position approaches the first opening 941. In the case of such a shape, as compared to the case where the front end portion is a straight line, a larger proportion of a cooling flow included in a cooling flow from the left side and flowing in a center portion reaches a part included in the heat radiation plate 103a and in the vicinity of the heat reception portion 107 before heated by the heat radiation plate 103a. Accordingly, a larger quantity of heat is radiated to the cooling flow from the part included in the heat radiation plate 103a and in the vicinity of the heat reception portion 107 having large heat flux. Thus, the mounting substrate 100 in FIG. 11 enables more satisfactory cooling of the CPU 105 than the mounting substrate 100 in FIG. 6.

### Advantageous Effects

In the mounting substrate according to the present example embodiment, a height of the side surface of the heat radiation plate becomes lower on more upstream and downstream sides of a cooling flow. Thus, in the mounting substrate, it is possible to suppress generation of vortexes occurring in the vicinity of a front end of the heat radiation plate group and in the vicinity of a rear end of the heat radiation plate group. The vortexes include components in a direction opposite to a direction of the cooling flow, and thus, because of existence of the vortexes, the cooling flow does not easily enter a part covered by the cover portion. However, generation of the vortexes is suppressed in the mounting substrate, and accordingly, a larger quantity of a cooling flow passes through an area around the heat radiation plate. Therefore, in the mounting substrate, heat is radiated from the heat radiation plate to the cooling flow more satisfactorily, and to that extent, the CPU is cooled more satisfactorily.

In the mounting substrate according to the present example embodiment, there is a case where the flow direction adjustment portion guiding a cooling flow to a part included in the heat radiation plate and in the vicinity of the heat reception portion is provided on the lower surface of the upper portion of the cover portion. From the thermal fluid analysis simulation, it is understood that a value of heat flux is larger at the part included in the heat radiation plate and in the vicinity of the heat reception portion. The flow direction adjustment portion guides a larger quantity of an unheated cooling flow to the part included in the heat radiation plate and in the vicinity of the heat reception portion having large heat flux, thereby cooling the part. Therefore, the flow direction adjustment portion enables more satisfactory cooling of the heat reception portion and the CPU.

In the mounting substrate according to the present example embodiment, there is a case where a side surface shape of a part included in the heat radiation plate and on a cooling-flow upstream side of the heat reception portion is convex downward and has a height becoming higher on a more downstream side of a cooling flow. In this case, in the mounting substrate, a larger quantity of an unheated cooling flow can be supplied to a part included in the heat radiation plate and in the vicinity of the heat reception portion. Therefore, the shape of the heat radiation plate enables more satisfactory cooling of the heat reception portion and the CPU.

Although the description is made above on the example of the case where the heat generation component cooled by the heat radiation component is the CPU, the heat generation component may be another one other than a CPU. A cooling flow that cools the heat radiation plate is typically an air flow, but may be a gas flow other than an air flow. The cooling flow may be also a liquid flow.

The above description is made on the case where on both sides of a first opening side and a second opening side, a height of the heat radiation plate from the wiring substrate becomes smaller as a distance from the heat reception portion increases. However, even when on only one of the first opening side and the second opening side, a height (distance) of an upper end of the heat radiation plate from the wiring substrate becomes smaller as a distance from the heat reception portion increases, it is possible to achieve an advantageous effect of suppressing a vortex occurring in a cooling flow. Thus, on only one of the first opening side and the second opening side, a height of an upper end of the heat radiation plate from the wiring substrate may become smaller as a distance from the heat reception portion increases.

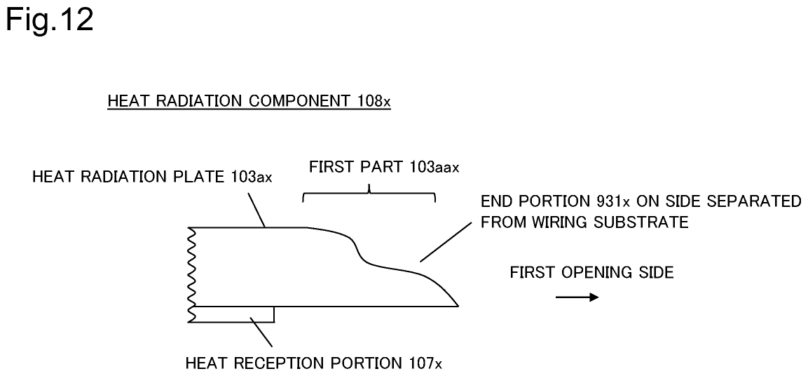

FIG. 12 is a concept diagram illustrating a configuration of a heat radiation component 108x as the minimum configuration of a heat radiation component according to an example embodiment. FIG. 12 illustrates a part of the heat radiation component 108x.

The heat radiation component 108x is assumed to be surrounded by a wiring substrate and a cover portion including a first opening and a second opening, which are not illustrated. The heat radiation component 108x includes a heat reception portion 107x contacting with a heat generation component installed in the wiring substrate, and a plurality of heat radiation plates 103ax thermally connected to the heat reception portion 107x. A first part 103aax as a part included in the heat radiation plate 103ax and between the heat generation component and the first opening includes an end portion 931x that is an end portion on a side more separated from the wiring substrate and whose distance from the wiring substrate decreases as a position approaches the first opening.

The first part 103aax of the heat radiation component 108x has a shape that becomes narrower as a position approaches the first opening.

Accordingly, a vortex generated in the first portion 103aax is suppressed not only when a cooling flow is caused to flow from the first opening to the second opening, but also when a cooling flow is caused to flow from the second opening to the first opening. Thus, a quantity of a flow passing through an area around the heat radiation plate can be increased without increasing force of sending out a cooling flow by a fan or the like. For this reason, the heat radiation component 108x can more satisfactorily cool the heat radiation plate. Heat of the heat radiation plate is conducted from the heat generation component. Thus, the heat generation component can be cooled more satisfactorily without increasing a flow pressure of a cooling flow.

Therefore, the heat radiation component 108x achieves the above-described advantageous effect by the above-described configuration.

While the invention has been particularly shown and described with reference to example embodiments thereof, the invention is not limited to these embodiments. It will be understood by those of ordinary skill in the art that various changes in form and details may be made therein without departing from the spirit and scope of the present invention as defined by the claims.

The whole or part of the example embodiments disclosed above can be described as, but not limited to, the following supplementary notes.

### (Supplementary Note 1)

A heat radiation component assumed to be surrounded by a wiring substrate and a cover portion that includes a first opening and a second opening, the heat radiation component including:

a heat reception portion contacting with a heat generation component installed on the wiring substrate; and

a plurality of heat radiation plates thermally connected to the heat reception portion, wherein,

a first part as a part included in the heat radiation plate and between the heat generation component and the first opening includes an end portion that is on a side more separated from the wiring substrate and whose distance from the wiring substrate decreases as being closer to the first opening.

### (Supplementary Note 2)

The heat radiation component according to Supplementary Note 1, wherein a degree of decrease of the distance in the first part decreases as being closer to the first opening.

### (Supplementary Note 3)

The heat radiation component according to Supplementary Note 1 or 2, wherein in a second part as a part included in the heat radiation plate and between the heat generation component and the second opening, the distance decreases as being closer to the second opening.

### (Supplementary Note 4)

The heat radiation component according to Supplementary Note 3, wherein in a third part as a part included in the heat radiation plate and between the first part and the second part, the distance is substantially constant.

### (Supplementary Note 5)

The heat radiation component according to any one of Supplementary Notes 1 to 4, wherein a cooling flow is assumed to flow from the first opening toward the second opening.

### (Supplementary Note 6)

The heat radiation component according to Supplementary Note 5, further including the cover portion.

### (Supplementary Note 7)

The heat radiation component according to Supplementary Note 6, wherein the cover portion includes a flow direction adjustment portion that guides the cooling flow to a part included in the heat radiation plate and in vicinity of the heat reception portion.

### (Supplementary Note 8)

The heat radiation component according to any one of Supplementary Notes 1 to 7, wherein the heat reception portion and the heat radiation plate are connected by a heat conduction plate.

### (Supplementary Note 9)

The heat radiation component according to Supplementary Note 8, wherein the heat radiation plate is substantially perpendicular to the heat conduction plate.

### (Supplementary Note 10)

A mounting substrate including the heat radiation component according to any one of Supplementary Notes 1 to 9 and the wiring substrate.

### (Supplementary Note 11)

The mounting substrate according to Supplementary Note 10, further including the heat generation component.

### REFERENCE SIGNS LIST

100 Mounting substrate
101 Heat conduction plate
102 Cover portion
103 Heat radiation plate group
103a, 103ax Heat radiation plate
103aax First part
104 Wiring substrate
105 CPU
106 Flow direction adjustment portion
106a Surface
107, 107x Heat reception portion
108, 108x Heat radiation component
921 Upper portion
931 Front end portion
931x End portion
941 First opening
942 Second opening
981a, 981b, 981c Cooling flow
991a, 991b Arrow

The previous description of embodiments is provided to enable a person skilled in the art to make and use the present invention. Moreover, various modifications to these example embodiments will be readily apparent to those skilled in the art, and the generic principles and specific examples defined herein may be applied to other embodiments without the use of inventive faculty. Therefore, the present invention is not intended to be limited to the example embodiments described herein but is to be accorded the widest scope as defined by the limitations of the claims and equivalents.

Further, it is noted that the inventor's intent is to retain all equivalents of the claimed invention even if the claims are amended during prosecution.

While the invention has been particularly shown and described with reference to example embodiments thereof, the invention is not limited to these embodiments. It will be understood by those of ordinary skill in the art that various changes in form and details may be made therein without departing from the spirit and scope of the present invention as defined by the claims.

1. A heat radiation component assumed to be surrounded by a wiring substrate and a cover portion that includes a first opening and a second opening, the heat radiation component comprising:
a heat reception portion contacting with a heat generation component installed on the wiring substrate; and
a plurality of heat radiation plates thermally connected to the heat reception portion, wherein,
in a first part as a part included in the heat radiation plate and between the heat generation component and the first opening, a distance from the wiring substrate to an end portion included in the heat radiation plate and on a side more separated from the wiring substrate decreases as being closer to the first opening.

2. The heat radiation component according to claim 1, wherein a degree of decrease of the distance in the first part decreases as being closer to the first opening.

3. The heat radiation component according to claim 1, wherein, in a second part as a part included in the heat radiation plate and between the heat generation component and the second opening, the distance decreases as being closer to the second opening.

4. The heat radiation component according to claim 3, wherein, in a third part as a part included in the heat radiation plate and between the first part and the second part, the distance is substantially constant.

5. The heat radiation component according to claim 1, wherein a cooling flow is assumed to flow from the first opening toward the second opening.

6. The heat radiation component according to claim 5, further comprising the cover portion.

7. The heat radiation component according to claim 6, wherein the cover portion includes a flow direction adjustment portion that guides the cooling flow to a part included in the heat radiation plate and in vicinity of the heat reception portion.

8. The heat radiation component according to claim 1, wherein the heat reception portion and the heat radiation plate are connected by a heat conduction plate.

9. The heat radiation component according to claim 8, wherein the heat radiation plate is substantially perpendicular to the heat conduction plate.

10. A mounting substrate comprising the heat radiation component according to claim 1 and the wiring substrate.

11. The mounting substrate according to claim 10, further comprising the heat generation component.
